(19) United States
(12) Patent Application Publication
(10) Pub. No.: US 2006/0068108 A1
(43) Pub. Date: Mar. 30, 2006

(54) Masking device and coating method

(76) Inventor: Volker Beckord, Hannover (DE)

Correspondence Address: CENTRAL COAST PATENT AGENCY, PO BOX 187, AROMAS, CA, 95004, US

(21) Appl. No.: 10/539,460

(22) PCT Filed: Dec. 22, 2003
(86) PCT No.: PCT/EP03/14742

§ 371 Date: Aug. 17, 2005

(30) Foreign Application Priority Data
Dec. 20, 2002 (DE) 10260215.8

(51) Int. Cl. B05D 1/02; B05C 11/11; C23C 14/00

(52) U.S. Cl. 427/256; 118/504; 427/421.1; 204/192.12

(57) ABSTRACT

Masking means (1) for masking of a longitudinally extended edge area of a vehicle body or an appliance housing during a coating process, in particular a painting or preservation process, with the arrangement of a longitudinally continuous cavity and slot (3) of the outer contour leading into it, whose boundary areas are elastically pre-tensioned to each other.

The invention is a masking means according to the generic term of claim 1 as well as a coating procedure performed with said masking means, in particular a painting or conservation procedure according to the generic term of claim 17.

The automobile painting process is currently one of the most technologically demanding paint applications. The most important demands are colour effect and gloss as well as protection of the metal surfaces from the elements. The desired properties of the paint are attained via the functional layer composition, in which the individual layers serve different purposes. First a cathodic dip-coating (CDC) is applied as an anti-corrosion layer on the body shell, which coating is burned in a drying oven at temperatures of up to 220 degrees Celsius. Only then does the primed body go on to the actual coating process, the first step of which is to apply a filler to even out the foundation and for protection against falling rocks. A base coat is then applied for colouring and special effects, and finally a clear coat for protection from external forces. The actual painting process carried out after the CDC layer is performed at temperatures of up to approx. 175° C.

After being run through the coating line, internals on the body of a vehicle are implemented. In particular, the window panes (windscreen, back window and fixed side windows) in large-scale production are generally installed and adhered robotically on the installation site (direct glazing). The window adhesive is first applied in beads around the border area of the window pane, before this area is brought into contact with and pressed onto the body flange (window flange) at the installation opening. The structural connection between the window and the body serves both for stabilization in the sense of a torsion-resistant body as well as force deflection in the event of a crash.

Since all layers sprayed on in the coating process, such as filler coat and topcoat, are applied according to the demands of the client, it is necessary that the window adhesive achieves good adhesion on many different topcoats (colours). However, the structural connection between the window and body in the assembly, where the coated surfaces are, is not adequately removed because the coat structure cannot bear the structural forces, particularly in a crash. Thus, in order to achieve good adhesion between the body flange and the window adhesive, it is optimal to adhere the windows on the CDC layer because this eliminates the structural weaknesses in the filler coat and topcoat. This kind of structural adhesion supports the lightweight construction trend and increases the torsion-resistance of the body. Though this procedure also requires a necessary masking of the body flange after running through the CDC coating to keep the coating layers applied in the subsequent coating steps away from this area. The masking provides flawless adhesion of the window adhesive to the CDC coated flange.

There is a well-known procedure for window adhesion in which the body flange is masked with an adhesive strip or with an organic mass, such as a PVC plastisol. The plastisol is set e.g. via IR radiation or in a PVC oven and thus attains a solid consistency. At the end of the coating process and before the installation of the windows, the flange masking is usually removed again and disposed of manually and the direct glazing is applied to the CDC coated flange. Neither the plastisol nor the adhesive strip is recyclable, which means that the disposal of the waste from the procedure is necessary to a considerable degree.

For this reason, the subject of a prior patent application (PCT/EP01/07501) from the applicant was an improved means (masking means) for the replacement of the adhesive strip. This means is an injection-moulded synthetic component applicable to the CDC coat with positive-locking. It is considerably easier to maintain than the aforementioned adhesive strip and is recyclable, which eliminates disposal costs and expenditures.

The object of this invention is to provide a further improved masking means of this kind, which in particular is economical to manufacture and can be easily maintained in various application situations.

This object is attained by a masking means with the features of claim 1. Appropriate further development of the idea of the invention is the subject of the attached claims. Moreover, this framework provides an improved coating procedure.

The design of the masking means as an extruded synthetic profile offers considerable cost savings in comparison to an injection-moulding part. Furthermore, the provision of the masking means as semi-continuous profile is conducive to a wide range of applications, since the masking means can be simply and easily adapted to the most distinct and unusual application situations by cutting it to suitable length.

In one of the currently favoured embodiments, the synthetic profile has been developed in cross-section in essentially circular, elliptical, oval or slanted oval shapes and as synthetic corrugated pipe with greater rigidity and lower elasticity in first portions and lower rigidity and greater elasticity in second portions.

O-form synthetic profiles are well-known from other areas of technology, for instance as “current-cable hoses”, and predominantly manufactured with the rotation extrusion procedure. Therefore, in principle, this masking means has established manufacturing technology and commercially available manufacturing plants. This greatly facilitates practical introduction in the cost parameters prescribed by the pressure of costs in large-scale automotive production. A masking means of this design-type is flexible (assuming the proper material and dimensioning) to such a high degree that the demands on the window flange masking in automobile coating can be met without limitation.

For special applications, it is a good idea, for further development in this design of the invention, that an additional bracket be provided to increase the contact pressure of the masking profile, particularly synthetic corrugated pipes, on the corresponding body section. This kind of bracket has a portion with an internal cross-section adapted to the external form of the masking profile and a sufficiently large opening which allows lateral movement on the masking profile in its state adapted to the body section. The favoured design also features an operation section for easy gripping of the bracket.

In particular, for other profile designs which do not attain such a high degree of flexibility in the primary moulding, an additional treatment is necessary for increased longitudinal flexibility. It is advantageous, for instance, to provide cuts that are tilted with respect to the long axis and longitudinally equidistant, which cut through the side of the profile in the large part of the level of the synthetic profile, for the creation of profile tabs joined together opposite the slot that tilt against each other but still essentially cover each other in areas of tight bending.

Depending on the specific technological formulation of the procedure for manufacture of cover profiles, a design in which the aforementioned cuts are not provided in the same sections or in which no cuts at all are provided over longer profile sections may be appropriate. If we have profile manufacturing controls adapted to a specific body shape, the provided curved areas of the profile can be shaped in this respect differently from the profile sections which will cover longitudinally extended edge areas.

This design with the aforementioned profile tabs (which could be viewed as a kind of fish scale) is particularly prudent in connection with an alternative profile design for the “synthetic corrugated pipe” mentioned above, in which the synthetic profile in cross-section essentially has a U-shape, in particular a “U” with sides of different lengths. This embodiment is in turn particularly favoured for further development in which the synthetic profile in cross-section has the form of a slanted “U” with a cavity expanding on the basis of the “U” for the elastically-bonded attachment on the edge area with different material thicknesses. The aforementioned U profile is suitable in a single design for practically all applications in the automobile coating sector, but also for other possible applications with different plate densities, for example in the coating of home appliances or industrial systems.

Considerable material savings are particularly possible with profile designs with partial relatively high lateral strengths, such as the recently mentioned slanted “U”, if the longitudinal side of the synthetic profile exhibits continuous, closed cavities for increasing the flexibility and decreasing the amount of material used.

For the aforementioned applications which have priority under the current viewpoint, a suitable synthetic profile design is one in which the cavity has a maximum width in the range of 3 to 12 mm and the continuous slot has a minimum free width of less than 1 mm, especially of 0.2 mm or less, for the elastically-bonded attachment on an edge area, particularly body/housing flange, with a minimum material thickness of roughly 0.5 mm and a maximum material thickness up to the range of 2.5 to 6 mm (depending on the profile construction).

In view of the temperatures occurring in the coating layers of the automobile production line, designs with high-grade temperature-resistant plastic are further favoured, which maintain the masking means properties that are essential to functioning at at least 175° C. for at least 25 min and further at least 155° C. for at least 75 min.

At any rate, for certain variations, such as the designs as essentially “smooth” U profiles, reinforcement via filler material with a quantity between 0.1% and 40% is functional. From the perspective of easy manufacture and handling, designs with a thermoplastic elastomer or polyamide are further favoured. In addition, plastics such as polysulphone and poly(arylether)ketone come under consideration, as indicated in A. Frank, Kunstoffkompendium, Vogel Fachbuch, fourth edition, 1996. For reinforcement material, for reasons related to cost, we particularly consider glass fibres, for special applications also carbon and synthetic fibres.

For environmental reasons, we favour a design of the masking means with a considerable quantity, in particular more than 75% and more particularly 90%, of recycled plastic. The designs can establish an essentially closed material flow cycle for the manufacturer of this kind of equipment and pose practically no disposal problems.

The proposed new type of masking means is not only applicable with coating or conservation processes in automotive or device construction (especially home appliance or entertainment electronics production). Rather, it also has other possible applications in the framework of liquid or powder spray processes, in which edges and/or openings of a product component—in particular, but not excluded to, part of the housing—must be protected before setting down the medium being applied. In principle, its application is therefore also possible in an advantageous manner in vacuum coating processes, and thus in particular high-vacuum vapour deposition processes and sputter processes.

The advantages and functionalities of the invention can be further seen from the claims below as well as the following description of two favoured designs based on the figures. These show:

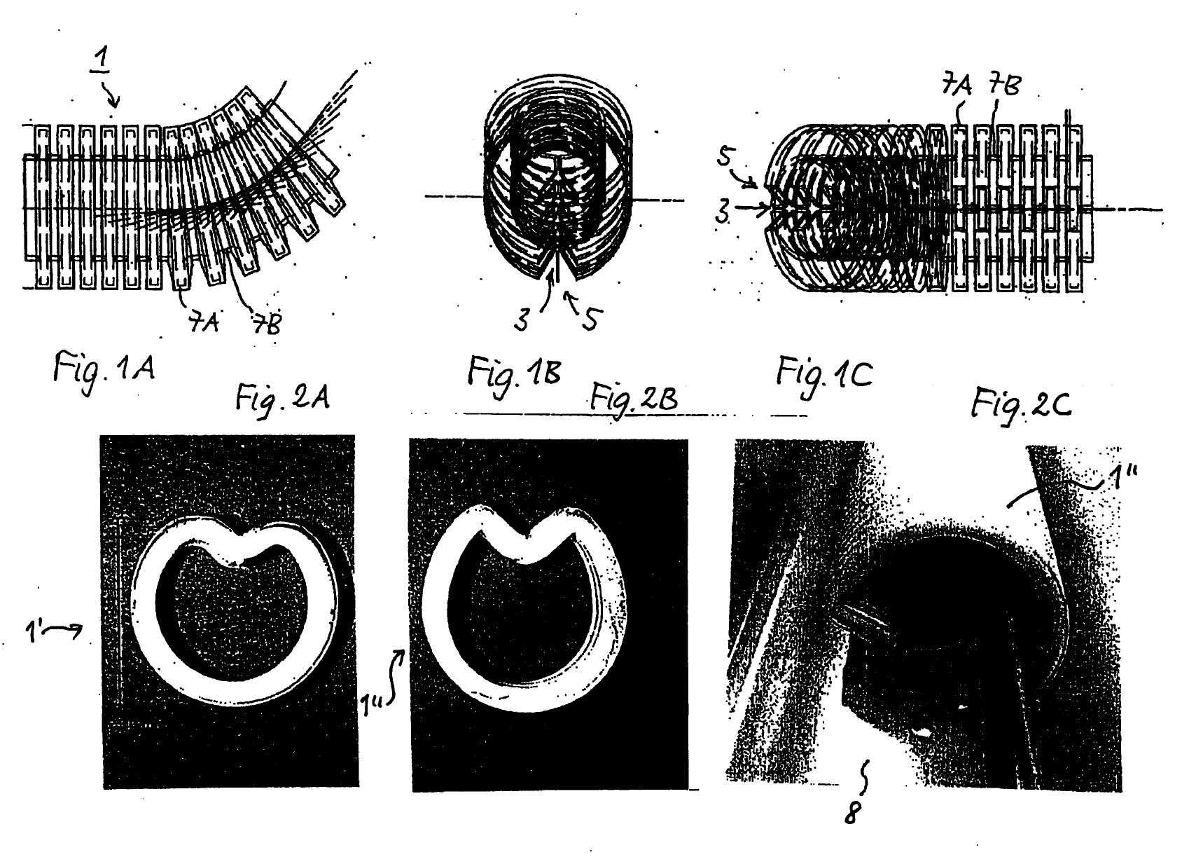

FIG. 1A to 1C different views (side view, front view and top view) of a masking means according to an initial design of the invention, applied to a bent window flange,

FIG. 2A to 2C Front views of designs of the masking means that are slightly modified in their particular form according to FIG. 1A to 1C, the latter also in an installation situation on an automobile tailgate panel,

FIGS. 3A and 3B Outline representation of a bracket appropriate for application with a masking means as per FIG. 1a to 2B, in perspective representation and/or representation of an installation situation,

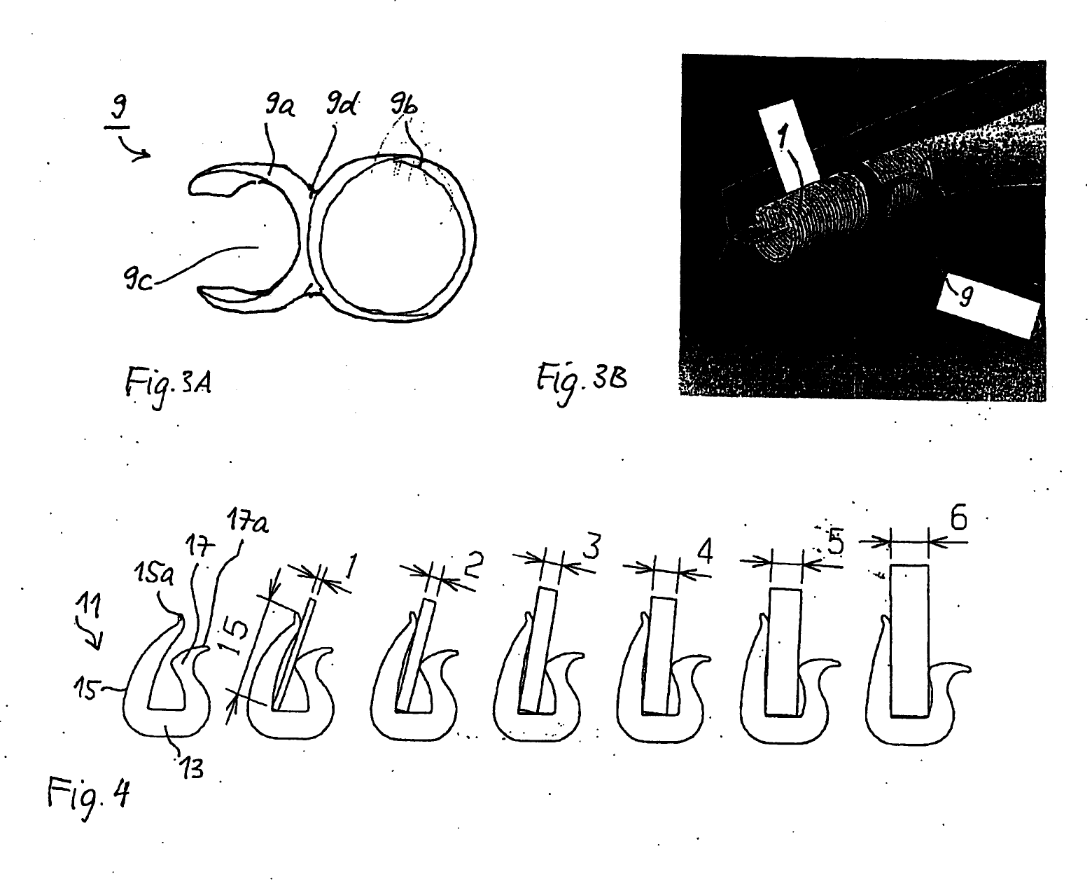

FIG. 4 a series of schematic cross-section representations of a masking means according to an additional design in different states, which features plates of different thickness, and

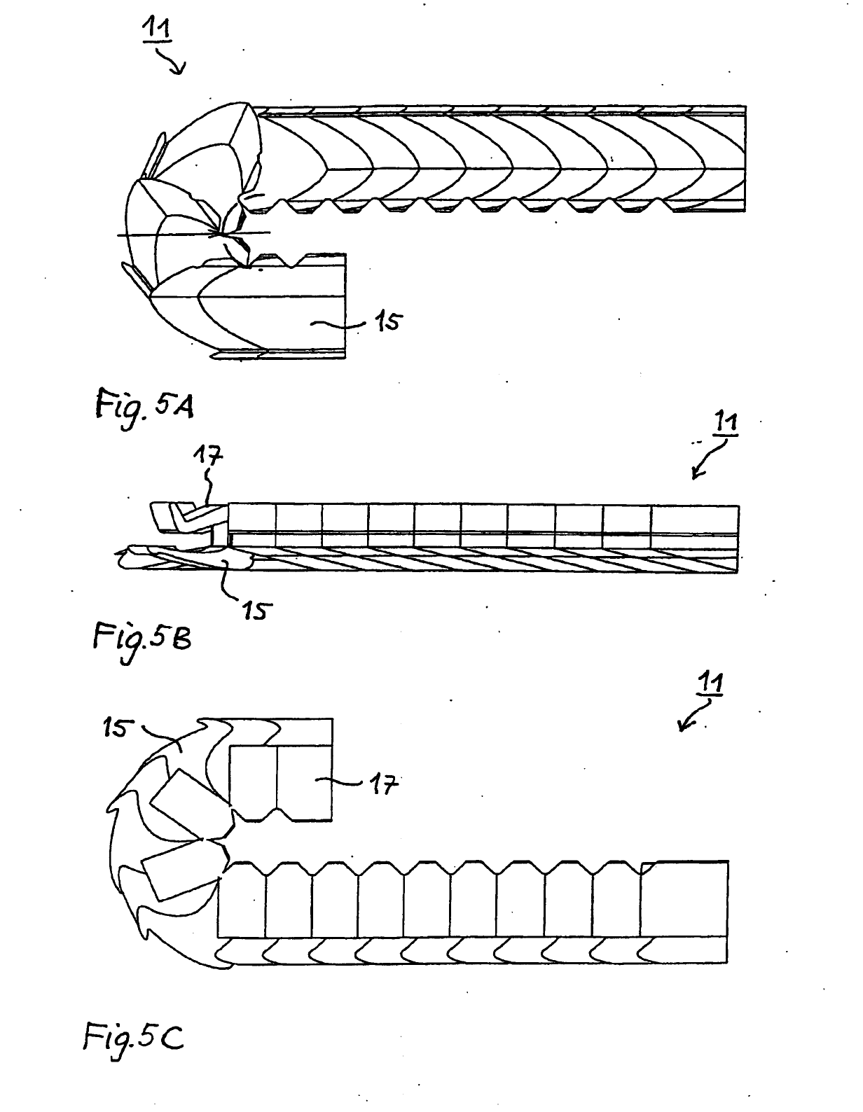

FIG. 5A to 5C Side views of the two sides (FIGS. 3A and 3C) as well as a top view of a masking means of the kind illustrated in FIG. 2, which is bent on one end in a very small radius.

FIG. 1A to 1C show a masking profile 1 manufactured via rotation extrusion in the form of a synthetic corrugated pipe, which exhibits a longitudinal slot 3 with V shaped mounting area 5. The synthetic corrugated pipe consists of integral, alternately ordered first rings 7A which are formed together, with larger diameters and two rings 7B with smaller diameters (which under certain conditions can exhibit low lateral strength and therefore high flexibility like the first rings 7A).

The outer diameter of the first rings 7A in the currently favoured design is between 16 and 20 mm, those rings of smaller diameter, if applicable, between 9 and 13 mm and the lateral strength at approx. 0.5 mm. The longitudinal slot 3 has a width of approx. 0.1 to 0.2 mm and the V shaped boundaries of the mounting area 7 which are-tilted toward each other, meet at an angle of roughly 60 to 75°.

FIGS. 2A and 2B show a front view and profile cross-section, respectively, of modified synthetic corrugated pipe, 1′ and 1″, respectively. In profile 1′ represented in FIG. 2A, the mounting area (not denoted separately here) is gently rounded and relatively flat in design, and the profile shape on the whole is somewhat levelled off with the circular cross-section. In the masking means 1″ represented in FIG. 2B, the outer contour in the cross-section is nearly circular and the mounting area is designed in a distinctive, clearly offset V shape. FIG. 2C shows the synthetic corrugated pipe 1″ in the states set up on the edge area of an automobile tailgate panel 8.

FIGS. 3A and 3B show a bracket 9 as additional element of a masking system when using a synthetic corrugated pipe in one of the designs described above, in order to increase its holding force on the body/housing section being covered. The bracket 9 has a roughly glasses-type basic form with a first, almost circular section 9a, which functions as a contact and holding section relative to a synthetic corrugated pipe, and a second circular (but entirely closed) section 9b, which serves as handling section in the set up of the bracket on a corrugated pipe and/or-the removal of this. The two sections, 9a and. 9b, are linked together by a web 9c. Of course that opening 9d in the contact and holding section 9a is adapted to the outer cross-section of the synthetic corrugated pipe in such a way that the bracket can be moved laterally over it relatively easily, on the other hand, this also reliably prevents it from coming off or from unintentional removal. The figures also demonstrate that, in the designs given here, the circular cross-section of the contact and holding section 9a is smaller, though its width is greater than that of the handling section 9b.

FIG. 4 to 5C show an alternative masking means design for synthetic corrugated pipe 1, viz., an extruded seal profile 11. It can be easily seen in FIG. 4 that this profile in the cross-section shape could be described as “slanted U-shaped”, since, from a base 13, a first, upward tapering side piece 15 and a second side piece 17 extend out in an asymmetrically tilting manner. Both of pieces, 15 and 17, exhibit an outward unwind, 15a and 17a, on their outer ends. As can also be seen in FIG. 4, this shape is excellently suited for secure mounting of the seal profile 11 on plates of widely differing thicknesses, anti-fog covering of the plate surface near the edges which is under (in the figure on the left) the side piece.

One can easily see in FIGS. 5A and 5C, how the height of the thoroughly executed cuts of the seal profile 11 that is ordered by diagonal to the longitudinal axis, is subdivided into individual layers or “scales”, which are only connected with each other on a relatively narrow, strip-shaped profile section. FIGS. 5A and 5C show, viewed from longer or shorter side pieces 15 or 17, how these layers spread apart when profile 11 is bent in a small radius. One will also notice that the longer profile side piece 15 also attains a very god covering of an underlying strip-shaped area (flange) in this extreme position of profile 11, as it occurs, for instance, in the “corners” of a window flange.

Both masking profiles 1 and 11 of the aforementioned first and second designs have as fundamental shared features a longitudinal slot, which expands into a cavity for the interior of the profile. In both designs, the sides of the slot are automatically pre-tensioned with respect to each other in a bracket-like way, so that the profile is automatically held in place by the friction force on a flange or other plate strip, on which it is slid open. It is common to both designs that the slot expands a bit more toward the periphery of the profile, which facilitates the attachment on the edges to be covered.

The design of the invention is not restricted to these examples, but also has numerous other possible adaptations within the framework of technical commerce. In particular, adaptations in the form of the two indicated masking profiles must be considered to exist for a wide array of variations as in the framework of the invention.

### KEY TO NUMBER REFERENCES

1;1′;1″ Masking Profile
3 Longitudinal slot
5 Mounting Area
7A First Ring
7B Automobile Tailgate Panel
9 Bracket
9a Contact and Holding Section
9b Handling Section
9c Web
9d Opening
11 Seal Profile
13 Base
15, 17 Side Pieces
15a, 17a Unwind Area

What is claimed is:

1. Masking means for masking of a longitudinally extended edge area of a vehicle body or an appliance housing during a coating procedure, in particular a paint or conservation process,
wherein
the development is as longitudinal high-grade flexible extruded synthetic profiles with a continuous longitudinal cavity and a slot in the outer contour leading into the cavity, whose boundary edges are elastically pre-tensioned to each other.

2. Masking means according to claim 1,
wherein
the synthetic profile design is in the cross-section essentially circular, elliptical, oval or slanted oval and as synthetic pipe with longitudinally alternating first portions of greater rigidity and lower elasticity and second portions of lower rigidity and greater elasticity.

3. Masking means according to claim 2,
wherein
the synthetic profile design is formed, via a rotation extrusion procedure, with longitudinally alternating first portions of greater rigidity and lower elasticity and second portions of lower rigidity and greater elasticity.

4. Masking means according to claim 1,
wherein
the synthetic profile in the slot area is essentially retracted V or U-shaped such that it automatically aligns itself on the longitudinally extended edge area when slid onto it.

5. Masking means according to claim 1,
wherein
longitudinally equidistant incisions are provided that are diagonal to the long axis, which cut through the profile side at the large part of the level of the synthetic profile, for the formation of profile tabs joined together opposite the slot that tilt against each other but still essentially cover each other in areas of tight bending.

6. Masking means according to claim 1,
wherein
the synthetic profile in the cross-section essentially has a U-shape, in particular with a “U” with side pieces of different lengths.

7. Masking means according to claim 6,
wherein
the synthetic profile in cross-section has the form of a slanted “U” with a cavity expanding on the basis of the “U” for the elastically-arrested attachment on the edge area with different material thicknesses.

8. Masking means according to claim 1,
wherein
the wall of the synthetic profile exhibits continuous, closed cavities extending in longitudinal direction, for increasing the flexibility and decreasing the amount of material used.

9. Masking means according to claim 1,
wherein
the cavity has a maximum width in the range of 3 to 12 mm and the continuous slot has a minimum free width of less than 1 mm, especially of 0.2 mm or less, for the elastically-arrested attachment on an edge area, particularly body/housing flange, with a minimum material thickness of roughly 1 mm and a maximum material thickness within the range of 2.5 to 6 mm.

10. Masking means according to claim 1,
wherein
the design is with high-grade temperature-resistant plastic, which maintains the masking means properties that are essential to functioning at least 175° C. for at least 25 min and also at least 155° C. for at least 75 min.

11. Masking means according to claim 1,
wherein
reinforcement is via filler material with a quantity between 0.1% and 40%.

12. Masking means according to claim 11,
wherein
the design is with a thermoplastic elastomer or polyamide.

13. Masking means according to claim 11,
wherein
a considerable quantity, in particular more than 75% and more particularly 90%, is of recycled plastic.

14. Masking arrangement with a masking means according to one of the above claims and a bracket attachable to the masking means for improved adhesion on the edge area.

15. Masking arrangement according to claim 14,
wherein
the bracket exhibits a contact and holding section in its inner contour on the outer contour of the masking means as well as handling section connected with this, particularly via a web.

16. Masking arrangement according to claim 14,
wherein
the contact and holding section and/or the handling section of the bracket essentially exhibits circular, elliptical or oval cross-section.

17. Coating process for coating a coating substrate, in particular a vehicle body or an aircraft fuselage or ship's hull or an appliance housing having a free edge area, with a coating means via a coating-spray stream or under a coating atmosphere, under coverage of the edge area,
wherein
the edge area is covered with a masking means according to one of the above claims.

18. Coating process according to claim 17,
wherein
the process is embodied as a procedure for the painting of a dip primer coated vehicle body or an appliance housing via a paint-spray stream.

19. Coating process according to claim 17,
wherein
the process is embodied as a process, in particular which is directly carried out after a painting process, for the conservation of a vehicle body or appliance housing, in particular an automobile body or an aircraft fuselage or ship's hull, via a conservation-spray stream.

20. Coating process according to claim 17,
wherein
the process is embodied as a vacuum coating process, in particular vacuum sputter or sputter processes, for creation of a thin protective or functional coating on the coating substrate.
